(19) United States
(12) Patent Application Publication
(10) Pub. No.: US 2023/0311172 A1
(43) Pub. Date: Oct. 5, 2023

(54) SUBSTRATE PROCESSING APPARATUS AND SUBSTRATE PROCESSING METHOD

(71) Applicant: SEMES CO., LTD., Chungcheongnam-do (KR)

(72) Inventors: Sung Hun EOM, Chungcheongnam-do (KR); Tae Won YUN, Chungcheongnam-do (KR)

(21) Appl. No.: 18/094,344

(22) Filed: Jan. 6, 2023

(30) Foreign Application Priority Data
Apr. 1, 2022 (KR) 10-2022-0041361

(51) Int. Cl. B08B 3/12; B08B 3/08

(52) U.S. Cl. CPC B08B 3/123; B08B 3/08

(57) ABSTRACT

A substrate processing apparatus includes a substrate support unit, supporting a substrate, and an ultrasonic cleaning module disposed in a location lower than an upper surface of the substrate support unit. The ultrasonic cleaning module may include a receiving portion receiving a chemical, an opening portion in which at least a portion of an upper surface of the receiving portion is opened, and an ultrasonic vibration unit disposed to be directed toward the opening portion from the receiving portion, and may be configured in such a manner that a liquid surface of the chemical, rising by the ultrasonic vibration unit, touches the substrate through the opening portion.

### CROSS-REFERENCE TO RELATED APPLICATION(S)

This application claims benefit of priority to Korean Patent Application No. 10-2022-0041361 filed on Apr. 1, 2022 in the Korean Intellectual Property Office, the disclosure of which is incorporated herein by reference in its entirety.

### BACKGROUND

### 1. Field

The present disclosure relates to a substrate processing apparatus and a substrate processing method.

### 2. Description of Related Art

Semiconductor manufacturing processes include a photolithography process in which a desired pattern is formed on a wafer. A photolithography process is performed in spinner local equipment to which exposure equipment is connected to continuously perform a coating process, an exposure process, and a developing process. Such spinner equipment may sequentially or selectively perform a coating process, a baking process, and a developing process.

In a coating process, a coating liquid is supplied from a nozzle to a rotating substrate. The coating liquid is diffused on the substrate by centrifugal force to form a coating film on the substrate.

After or during the coating process, a liquid treatment operation is performed to remove the coating liquid attached to a rear surface of the substrate. In the liquid treatment operation, a chemical is sprayed onto the rear surface of the substrate to remove the coating liquid.

In the case of the liquid treatment, the chemical is sprayed onto a lower surface of the substrate using a nozzle. The sprayed chemical is shaken off while the substrate rotates about a rotational axis. However, the sprayed chemical may be incompletely removed depending on properties of the coating liquid.

Patent Document 1 discloses a technology for cleaning an object to be cleaned (also referred to as a ‘cleaning target’). According to Patent Document 1, a chemical is applied to an upper surface of a substrate, and ultrasonic waves are then applied to clean the cleaning target. However, the technology uses a water film formed by gravity and surface tension, so only an upper portion of the cleaning target may be cleaned.

Patent Document 1: Japanese Patent No. 5,453,582 B

### SUMMARY

The present disclosure has been made to improve cleaning of a lower portion of a substrate. Accordingly, an aspect of the present disclosure is to provide a substrate processing apparatus and a substrate processing method for cleaning a lower portion of a substrate using ultrasonic waves.

According to an aspect of the present disclosure, a substrate processing apparatus includes a substrate support unit, supporting a substrate, and an ultrasonic cleaning module disposed in a location lower than an upper surface of the substrate support unit. The ultrasonic cleaning module may include a receiving portion receiving a chemical, an opening portion in which at least a portion of an upper surface of the receiving portion is opened, and an ultrasonic vibration unit disposed to be directed toward the opening portion from the receiving portion, and may be configured in such a manner that a liquid surface of the chemical, rising by the ultrasonic vibration unit, touches the substrate through the opening portion.

The opening portion may open an upper surface of the receiving portion with a shape corresponding to a shape of the ultrasonic vibration unit when viewed from above.

The receiving portion may further include a supply pipe connected to a chemical supply pipe configured to supply the chemical, and an area of the opening portion may be larger than a cross-sectional area of the supply pipe.

The substrate processing apparatus may further include a vertical movement unit connected to the ultrasonic cleaning module and moving the ultrasonic cleaning module in a vertical direction.

The substrate support unit may be configured to rotate about a rotational axis of the substrate support unit, and a maximum distance from the rotational axis of the substrate support unit to the ultrasonic vibration unit may be greater than a maximum radius of the substrate.

According to another aspect of the present disclosure, a substrate processing apparatus includes a substrate support unit supporting a substrate and configured to rotate about a rotational axis, an ultrasonic cleaning module disposed on an external side of the substrate support unit in a location lower than an upper surface of the substrate support unit, a lower plate surrounding the substrate support unit below the substrate support unit and on which the ultrasonic cleaning module is seated, and at least one cup covering an external side of the substrate support unit. The ultrasonic cleaning module may include a receiving portion receiving a chemical, an opening portion in which at least a portion of an upper surface of the receiving portion is opened, and an ultrasonic vibration unit disposed to be directed toward the opening portion from the receiving portion, and is configured in such a manner that a liquid surface of the chemical, rising by the ultrasonic vibration unit, touches the substrate through the opening portion. The ultrasonic vibration unit may extend in a radial direction of the substrate, and a first length of the ultrasonic vibration unit in a radial direction of the substrate may be greater than a second length of the ultrasonic vibration unit in a direction, perpendicular to the radial direction.

According to another aspect of the present disclosure, a method for processing a substrate using a substrate processing apparatus including a substrate support unit, supporting a substrate, and an ultrasonic cleaning module including a receiving portion receiving a chemical and an ultrasonic vibration unit disposed to be directed toward an upper surface from the receiving portion and disposed to be lower than an upper surface of the substrate support unit is provided. The method includes: a liquid surface rising operation in which, by operating the ultrasonic vibration unit, a liquid surface of the chemical received in the receiving portion rises to bring the chemical into contact with a lower surface of a substrate; and a cleaning operation in which the lower surface of the substrate, being rotated, is cleaned while the liquid surface rises.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a view of a substrate processing apparatus when viewed from above.

FIG. 2 is a view of the substrate processing apparatus of FIG. 1 when viewed in direction A-A.

FIG. 3 is a view of the substrate processing apparatus of FIG. 1 when viewed in direction B-B.

FIG. 4 is a schematic view illustrating a state in which a lower nozzle unit is disposed on a lower plate in a substrate processing apparatus.

FIG. 5 is a schematic view illustrating a state in which a chemical is injected to a substrate by a lower nozzle unit in the substrate processing apparatus of FIG. 4.

FIG. 6 is a schematic diagram of a substrate processing apparatus according to an embodiment of the present disclosure.

FIG. 7A is a schematic diagram of an ultrasonic cleaning module in operation, FIG. 7B is an image of the ultrasonic cleaning module in operation, and FIG. 7C is a partially schematic view of a substrate processing apparatus in operation.

FIG. 8 is a plan view of the substrate processing apparatus according to the embodiment of FIG. 6.

FIGS. 9A and 9B are a schematic view and a schematic perspective view of an ultrasonic cleaning module according to another embodiment of the present disclosure.

FIG. 10 is a schematic view of an ultrasonic cleaning module according to another embodiment of the present disclosure.

FIG. 11 is a plan view of a substrate processing apparatus according to another embodiment of the present disclosure.

FIG. 12 is a schematic diagram of a substrate processing apparatus according to another embodiment of the present invention.

FIG. 13 is a schematic diagram of a substrate processing apparatus according to another embodiment of the present disclosure.

FIGS. 14A and 14B are a plan view and a partially cross-sectional view of a substrate processing apparatus according to another embodiment of the present disclosure, respectively.

FIG. 15 is a schematic view of a substrate processing apparatus according to another embodiment of the present disclosure.

### DETAILED DESCRIPTION

Hereinafter, preferred embodiments will be described in detail such that those of ordinary skill in the art easily practices the present disclosure with reference to the accompanying drawings. However, in describing a preferred embodiment of the present disclosure in detail, if it is determined that a detailed description of a related known function or configuration unnecessarily obscures the gist of the present disclosure, the detailed description thereof will be omitted. In addition, the same reference numerals may be used throughout the drawings for parts having similar functions and operations. In addition, in this specification, terms such as ‘on,’ ‘upper portion,’ ‘upper surface,’ ‘below,’ ‘lower portion,’ ‘lower surface,’ ‘side surface,’ and the like may be based on the drawings, and in fact, may be changed depending on a direction in which components is disposed.

In addition, throughout the specification, when a portion is ‘connected’ to another portion, may include not only ‘directly connected.’ but also ‘indirectly connected’ to other components interposed therebetween. In addition, ‘including’ a certain component means that other components are further included, rather than excluding other components, unless otherwise stated.

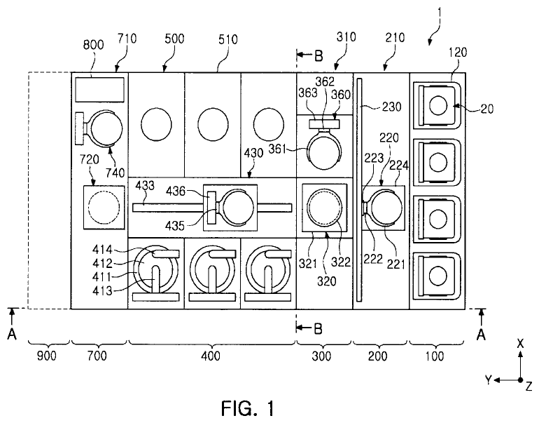

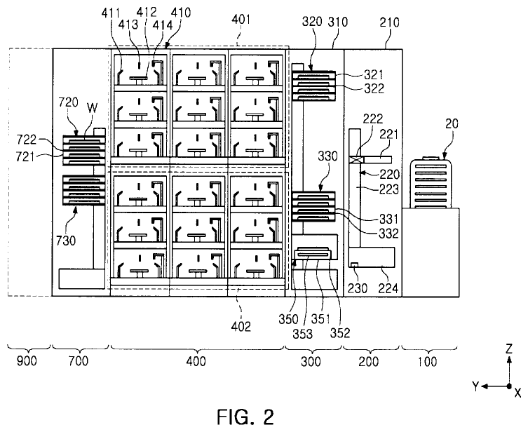

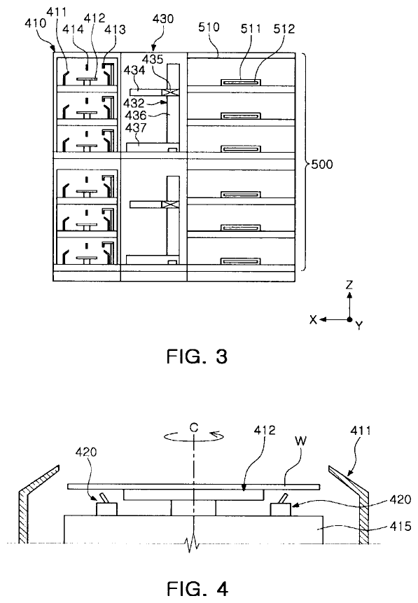

FIGS. 1 to 3 are schematic views of a substrate processing apparatus 1 according to an example embodiment. FIG. 1 is a view of the substrate processing apparatus 1 when viewed from above, FIG. 2 is a view of the substrate processing apparatus 1 of FIG. 1 when viewed in direction A-A, and FIG. 3 is a view of the substrate processing apparatus 1 of FIG. 1 when viewed in direction B-B.

Referring to FIGS. 1 to 3, the substrate processing apparatus 1 may include a load port 100, an index module 200, a buffer module 300, a coating and developing module 400, and a purge module 800. The load port 100, the index module 200, the buffer module 300, the coating and developing module 400, and an interface module 700 may be sequentially arranged in a row in one direction. The purge module 800 may be provided in the interface module 700. Alternatively, the purge module 800 may be provided in various locations such as a location to which an exposure apparatus at a rear end of the interface module 700 is connected, a side portion of the interface module 700, or the like.

Hereinafter, a direction in which the load port 100, the index module 200, the buffer module 300, the coating and developing module 400, and the interface module 700 are arranged will be referred to as a first direction Y, a direction, perpendicular to the first direction Y when viewed above will be referred to as a second direction X, and a direction, perpendicular to both the first direction Y and the second direction X, will be referred to as a third direction Z.

The substrate W is moved while being accommodated in the cassette 20. The cassette 20 has a structure which may be sealed from the outside. For example, a front open unified pod (FOUP) having a door on a front side may be used as the cassette 20.

Hereinafter, the load port 100, the index module 200, the buffer module 300, the coating and developing module 400, the interface module 700, and the purge module 800 will be described in detail.

The load port 100 may include a loading table on which the cassette 20, in which the substrate W is accommodated, is loaded. A plurality of mounting tables 120 may be provided. The plurality of mounting tables 120 may be arranged in a row in a second direction X. In FIG. 2, four mounting tables 120 are provided, but the number of the mounting tables may vary according to example embodiments.

The index module 200 may transfer a substrate W between the cassette 20, loaded on the loading table 120 of the load port 100, and the first buffer module 300. The index module 200 may include a frame 210, an index robot 220, and a guide rail 230. The frame 210 may be provided to have a substantially hollow cuboidal shape, and may be disposed between the load port 100 and the first buffer module 300. The frame 210 of the index module 200 may be provided to have a height, smaller than a height of a frame 310 of the first buffer module 300. The index robot 220 and the guide rail 230 may be disposed in the frame 210. The index robot 220 may be provided such that a hand 221, directly handling a substrate W, is movable and rotatable in the first direction X, the second direction Y, and the third direction Z. The index robot 220 may include a hand 221, an arm 222, a support 223, and a prop 224. The hand 221 may be fixedly installed in the arm 222. The arm 222 may be provided to have a flexible and rotatable structure. The support 223 may be provided such that a length direction thereof extends in the third direction Z. The arm 222 may be coupled to the support 223 to be movable along the support 223. The support 223 may be fixedly coupled to the prop 224. The guide rail 230 may be provided such that a length direction thereof extends in the second direction X. The prop 224 may be coupled to the guide rail 230 to be linearly movable along the guide rail 230. Although not illustrated, the frame 210 may be further provided with a door opener opening and closing a door of the cassette 20.

The buffer module 300 may include a frame 310, a first buffer 320, a second buffer 330, a cooling chamber 350, and a first buffer robot 360. The frame 310 may be provided to have a hollow cuboidal shape, and may be disposed between the index module 200 and the coating and developing module 400. The first buffer 320, the second buffer 330, the cooling chamber 350, and the first buffer robot 360 may be disposed in the frame 310. The cooling chamber 350, the second buffer 330, and the first buffer 320 may be sequentially disposed from below in the third direction Z. The first buffer 320 may be disposed at a height corresponding to a coating module 401 of the coating and developing module 400, and the second buffer 330 and the cooling chamber 350 may be provided at a height corresponding to the module 402 of the coating and developing module 400. The first buffer robot 360 may be disposed to be spaced apart from the second buffer 330, the cooling chamber 350, and the first buffer 320 by a predetermined distance in the second direction X.

The first buffer 320 and the second buffer 330 may temporarily preserve a plurality of substrates W. The second buffer 330 may have a housing 331 and a plurality of supports 332. The supports 332 may be disposed within the housing 331, and may be provided to be spaced apart from each other in the third direction 16. A single substrate W may be disposed on each of the supports 332. The housing 331 may have openings, not illustrated, in a direction, in which the index robot 220 is provided, and in a direction, in which the first buffer robot 360 is provided, such that the index robot 220 and the first buffer robot 360 carries a substrate W into or out of the support 332 in the housing 331. The first buffer 320 may have a structure, substantially similar to a structure of the second buffer 330. The housing 321 of the first buffer 320 may be provided with an opening in a direction, in which the first buffer robot 360 is provided, and in a direction in which a coating robot 432 disposed in the coating module 401 is provided. The number of supports 322 provided for the first buffer 320 and the number of supports 332 provided for the second buffer 330 may be the same or different. As an example, the number of the supports 332 provided for the second buffer 330 may be larger than the number of the supports 332 provided for the first buffer 320.

The first buffer robot 360 may transfer a substrate W between the first buffer 320 and the second buffer 330. The first buffer robot 360 may include a hand 361, an arm 362, and a support 363. The hand 361 may be fixedly installed in the arm 362. The arm 362 may be provided to have a flexible structure, allowing the hand 361 to be moved in the second direction 14. The arm 362 may be coupled to the support 363 to be linearly movable along the support 363 in the third direction 16. The support 363 may have a length extending from a location corresponding to the second buffer 330 to a location corresponding to the first buffer 320. The support 363 may be provided to extend further in an upward or downward direction. The first buffer robot 360 may be provided such that the hand 361 is simply two-axis driven in the second direction 14 and the third direction 16.

The cooling chamber 350 may cool a substrate W. The cooling chamber 350 may include a housing 351 and a cooling plate 352. The cooling plate 352 may include a cooling unit 353 cooling an upper surface of the cooling chamber 350, on which the substrate W is disposed, and the substrate W. Various types, such as a cooling type using cooling water and a cooling type using a thermoelectric element, may be used as the cooling unit 353. A lift pin assembly may be provided in the cooling chamber 350 to locate the substrate W on the cooling plate 352. The housing 351 may have openings, not illustrated, in a direction, in which the index robot 220 is provided, and in a direction, in which a developing robot is provided, such that the index robot 220 and the developing robot 482 provided for the development robot 402 move the substrate W into or out of the cooling plate 352. The cooling chamber 350 may be provided with doors opening and closing the above-mentioned openings.

The coating module 401 may perform a process of coating a photosensitive liquid such as a photoresist on a substrate W and a heat treatment process of, for example, heating and cooling the substrate W before and after the resist coating process. The coating module 401 may include a coating chamber 410, a bake chamber unit 500, and a transfer chamber 430. The coating chamber 410, the transfer chamber 430, and the bake chamber unit 500 may be sequentially disposed in the second direction X. For example, with respect to the transfer chamber 430, the coating chamber 410 may be provided on one side of the transfer chamber 430, and the bake chamber unit 500 may be provided on the other side of the transfer chamber 430.

A plurality of coating chambers 410 may be provided. The plurality of coating chambers 140 may be provided in the first direction Y, and may also be provided in the third direction Z. The bake chamber unit 500 may include a plurality of bake chambers 510, and the plurality of bake chambers 510 may be provided in the first direction Y and may also be provided in the third direction Z. The transfer chamber 430 may be disposed to be parallel to the first buffer 320 of the first buffer module 300 in the first direction 12. The coating robot 432 and the guide rail 433 may be disposed in the transfer chamber 430. The transfer chamber 430 may have a substantially rectangular shape. The coating robot 432 may transfer the substrate W between the bake chamber 510, the coating chamber 410, and the first buffer 320 of the first buffer module 300.

The guide rail 433 may be disposed such that a length direction thereof is parallel to the first direction Y. The guide rail 433 may guide the coating robot 432 to move linearly in the first direction Y. The coating robot 432 may have a hand 434, an arm 435, a support 436, and a prop 437. The hand 434 may be fixedly installed in the arm 435. The arm 435 may be provided to have a flexible structure, such that the hand 434 is movable in a horizontal direction. The support 436 may be provided such a length direction thereof extends in the third direction Z. The arm 435 may be coupled to the support 436 to be linearly movable along the support 436 in the third direction Z. The support 436 may be fixedly coupled to the prop 437, and the prop 437 may be coupled to the guide rail 433 to be movable along the guide rail 433.

All of the coating chambers 410 may have the same structure, but the types of chemical solution used in the coating chambers 410 may be different from each other. A chemical for formation of a photoresist film or an anti-reflective film may be used as the chemical.

The coating chamber 410 may coat a chemical on the substrate W. The coating chamber 410 may include a cup 411, a substrate support 412, and a nozzle 413. The cup 411 may have an open top side. The substrate support 412 may be disposed in the cup 411 and may support the substrate W. The substrate support 412 may be provided to be rotatable. The nozzle 413 may supply a chemical to the substrate W loaded on the substrate support 412. The chemical may be coated on the substrate W in a spin-coating manner. The coating chamber 410 may be further provided with a nozzle 414, supplying a cleaning solution such as deionized water (DIW) to clean a surface of the substrate W coated with the chemical, and a back-rinse nozzle, not illustrated, for cleaning a lower surface of the substrate W.

The bake chamber 510 may include a substrate support unit 511 and a heater 512 inside the substrate support unit 511, and the coating robot 432 may thermally treat the substrate W when the substrate W is seated on the substrate support unit 511.

The interface module 700 may connect the coating and developing module 400 to an external exposure apparatus 900. The interface module 700 may include an interface frame 710, a first interface buffer 720, a second interface buffer 730, and a transfer robot 740, and the transfer robot 740 may transfer a substrate, transferred to the first and second interface buffers 720 and 730 when coating and developing processes are finished, to the exposure apparatus 900. The first and second interface buffers 720 may include a housing 721 and a support 722, and the transfer robot 740 and the coating robot 432 may move the substrate W into or out of the support 722.

In the coating chamber 410, a liquid processing operation may be performed to remove the chemical attached to a rear surface of a substrate during or after a coating process. In the liquid processing operation, a chemical may be sprayed through the back-rinse unit to remove a coating solution.

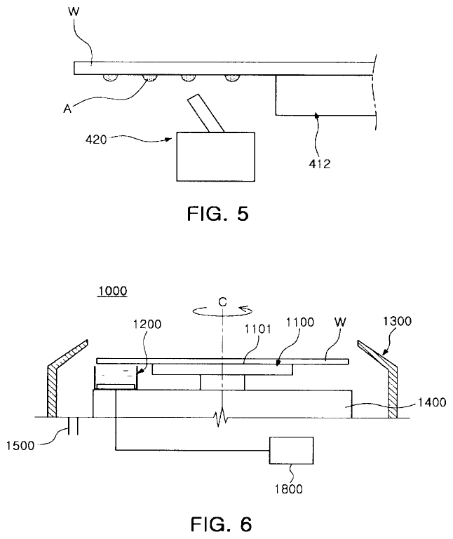

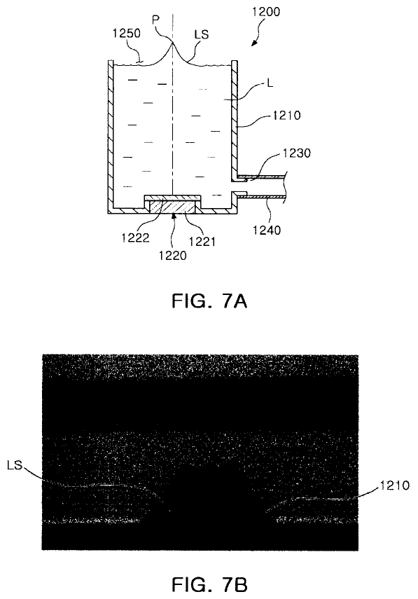

FIG. 4 is a schematic view illustrating a state in which a lower nozzle unit 420 is disposed on a lower plate 142, and FIG. 5 is a schematic view illustrating a state in which a chemical is injected to a substrate W by the lower nozzle unit 420.

The substrate processing apparatus may include a substrate support 412 supporting a substrate W, a cup 411 having an open upper portion surrounding the substrate support 412, a lower nozzle unit 420 disposed to be directed toward the substrate W below the substrate support unit 412, and a lower plate 415 on which the lower nozzle unit 420 is supported.

When the lower nozzle unit 420 injects a chemical while the substrate support 412 rotates, the chemical may be condensed on a lower surface of the substrate W. The condensed chemical may drop to the substrate support unit 412 by rotating the substrate W. The chemical, separated from the substrate W, may rebound from the cup 411 to recontaminate upper/lower portions of the substrate W and may be incompletely removed depending on viscosity or chemical characteristics of the applied chemical.

On the other hand, it may be considered that ultrasonic waves are provided to remove contaminants. However, as illustrated in FIG. 5, a lower portion of the substrate W may be unstable due to a liquid film formed by gravity and surface tension, so that it may be difficult to clean the substrate W by providing ultrasonic waves to the injected chemical.

In example embodiments, based on the fact that a liquid film rises in a direction, in which ultrasonic waves travel, when the ultrasonic waves are provided to a storage portion in which the chemical is stored, the rising liquid film may be brought into a lower surface of a substrate W to clean the lower surface of the substrate W.

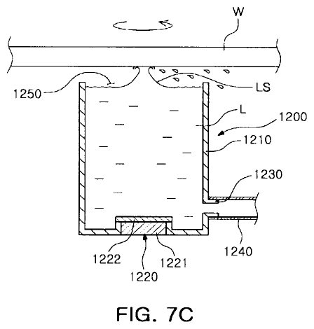

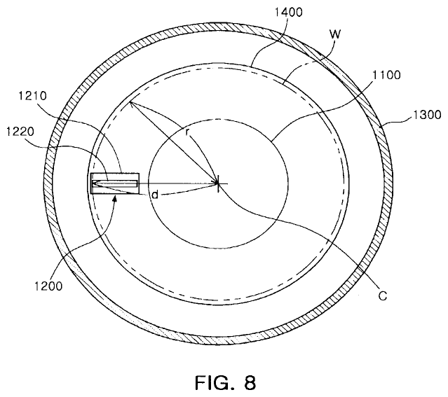

FIG. 6 is a schematic diagram of a substrate processing apparatus according to an embodiment of the present disclosure, FIG. 7A is a schematic diagram of an ultrasonic cleaning module in operation, FIG. 7B is an image of the ultrasonic cleaning module in operation, and FIG. 7C is a partially schematic view of a substrate processing apparatus in operation.

As illustrated in FIG. 6, a substrate processing apparatus 1000 according to an embodiment may include a substrate support unit 1100 supporting a substrate W, an ultrasonic cleaning module 1200 disposed on a level, lower than a level of an upper surface of the substrate support unit 1100, a cup 1300 surrounding the substrate support unit 1100, a lower plate 1400 surrounding the substrate support unit 1100 below the substrate support unit 1100, a discharge pipe 1500 connected to a lower portion between the cup 1300 and the lower plate 1400, and a control unit 1800 connected to the ultrasonic cleaning module 1200. The ultrasonic cleaning module 1200 may include a receiving portion 1210 receiving the chemical L, an open portion 1250 through which at least a portion of an upper surface of the receiving portion 1210 is opened, and an ultrasonic vibration unit 1220 disposed to be directed toward the opening 1250 from the receiving unit 1210, and may be configured such that a liquid surface of the chemical L rising by the ultrasonic vibration unit 1220 contacts the substrate W through the opening portion 1250.

The substrate support unit 1100 may be provided to support the substrate W, and may be connected to a driving unit to be rotatable about a central axis C. The substrate support unit 1100 may have an upper surface 1101, and the substrate support unit 1100 may rotate while the substrate W is seated on the upper surface 1101.

The ultrasonic cleaning module 1200 may be disposed below an upper surface of the substrate support unit 1100, for example, a lower surface of the substrate W to clean the lower surface of the substrate W, and may include a receiving portion 1210 in which the chemical L is received, an opening portion 1250 exposing at least a portion of an upper surface of the receiving portion 1210, and an ultrasonic vibration unit 1220 corresponding to the opening portion 1250 when viewed from above, for example, disposed on an internal side of the opening 1250 when viewed from above. The chemical L may include a solvent, a cleaning liquid, deionized water (DIW), and a lower portion coating liquid, and is not limited as long as it is a liquid. The ultrasonic cleaning module 1200 will be described once more while providing a description with reference to FIG. 7A.

The cup 1300 may be configured to prevent the chemical L contacting the lower surface of the substrate W from scattering, due to the ultrasonic cleaning module 1200, and may have an opened upper surface. A discharge pipe 1500 may be connected to a lower portion of an internal side of the cup 1300, and the substrate support unit 1100, the ultrasonic cleaning module 1200, and the lower plate 1400 may be disposed on the internal side of the cup 1300. Although not illustrated, the substrate processing apparatus 1000 may include an upper nozzle (see 413 and 414 of FIG. 2), and the cup 1300 may also serve to guide a chemical, scattered by the upper nozzle, to the discharge pipe 1500.

The lower plate 1400 may be configured to seat the ultrasonic cleaning module 1200 thereon. The lower plate 1400 may be disposed below the ultrasonic cleaning module 1200, and may surrounds the substrate support unit 1100. Alternatively, the substrate support 1100 may also be rotatably connected to the lower plate 1400. A discharge path may be formed in the lower plate 1400 to discharge the chemical L, scattered by rotation after contacting the lower surface of the substrate W in the ultrasonic cleaning module 1200, to the discharge pipe 1500.

The discharge pipe 1500 may be configured to discharge a chemical, supplied from the ultrasonic cleaning module 1200 or the upper nozzle and collected by the cup 1300, an external entity of the apparatus.

The control unit 1800 may be connected to the ultrasonic vibration unit 1220 of the ultrasonic cleaning module 1200, and may control an output of the ultrasonic vibration unit 1220. Even when the ultrasonic vibration unit 1220 generates ultrasonic waves having the same frequency, a height of the rising liquid surface varies depending on the output. Therefore, the control unit 1800 may control the output of the ultrasonic vibration unit 1120 in consideration of a distance between the ultrasonic cleaning module 1200 and the lower surface of the substrate W.

The ultrasonic cleaning module 1200 will be described with reference to FIGS. 7A to 7C. As illustrated in FIG. 7A, the ultrasonic cleaning module 1200 may include a supply pipe 1240 connected to the receiving portion 1210. The receiving portion 1210 may be provided with a connection portion 1230 for connection to the supply pipe 1240. The ultrasonic vibration unit 1220 may be disposed directly below the opening 1250, and may include a vibration element 1221 and a vibration plate 1222 disposed between the vibration element 1221 and the chemical L inside the receiving portion 1210 and transmitting a vibration of the vibration element 1221 to the chemical L.

In the case of a liquid medium, when ultrasonic waves are transmitted, a liquid surface LS may rise in a direction in which the ultrasonic waves travel. In particular, when a frequency of the ultrasonic wave is about 40 KHz or more and an output is sufficient because ultrasonic waves have linearity, a height of the liquid surface LS may be increased, as compared with that before the ultrasonic waves are provided. The frequency of the ultrasonic wave may be, in detail, 40 KHz or more and, in more detail, 100 KHz or more.

For example, as illustrated in FIGS. 7A and 7B, the liquid surface LS may vary depending on the output when the frequency of ultrasonic wave is 1 MHz but rises by about 1 cm to about 1.5 cm. Since a peak P of the rising liquid surface LS is disposed in a direction in which the ultrasonic waves are generated by an ultrasonic vibration element 1221, the ultrasonic vibration unit 1220 may be disposed to be directed toward the opening portion 1250. The peak P of the liquid surface LS may be provided in plural, rather than singular, depending on a width of the ultrasonic vibration element 1221. For example, when the width of the ultrasonic vibration element 1221 is about 4 cm, two peaks P may be formed on the liquid surface LS.

In the ultrasonic cleaning module 1200 according to an embodiment, the rising liquid surface LS may touch the lower surface of the substrate W using the rise of the liquid surface LS occurring due to the ultrasonic vibration unit 1220. When the liquid surface LS is brought into contact with the lower surface of the substrate W, the ultrasonic waves may reach the lower surface of the substrate W using the chemical liquid L as a medium and may be helpful in removing foreign objects or coating liquid from the lower surface of the substrate W.

As illustrated in FIG. 7C, the liquid surface LS is in contact with the lower surface of the substrate W while the substrate W rotates, the chemical L may be scattered to an external entity of the ultrasonic cleaning module 1200 by rotational force of the substrate W while containing foreign objects or the coating liquid. The ultrasonic cleaning module 1200 may include a supply pipe 1240 and a connection portion 1230 to supplement such a consumed chemical.

The supply pipe 1240 may be connected to a chemical supply unit, not illustrated, and may supply a chemical from the chemical supply unit to the receiving portion 1210. The chemical inside the receiving portion 1210 may be scattered to the outside to be consumed after the liquid surface rises due to the ultrasonic vibration unit 1220, and at least an amount of the consumed chemical may be supplemented by the supply pipe 1240. In addition, when the amount of the chemical solution supplied from the supply pipe 1240 is large, it is helpful in the rise of the liquid surface of the chemical L of the opening portion 1250, so that it is advantageous to supply a sufficient amount of chemical through the supply pipe 1240.

In the ultrasonic cleaning module 1200 according to an embodiment, the liquid surface LS of the chemical liquid L may rise through the opening portion 1250 and the substrate W may be cleaned by the rising liquid surface LS. Therefore, the opening 1250 portion is required to be opened with a sufficiently large area and may be opened with at least a larger area than the ultrasonic vibration unit 1220.

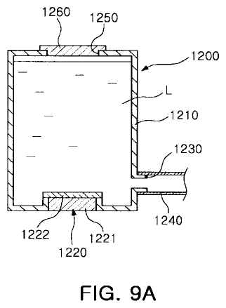

FIG. 8 is a plan view of the substrate processing apparatus 1000 according to the embodiment of FIG. 6. The substrate support unit 1100 may rotate about a central axis C, and the central axis C of the substrate support 1100 may correspond to a center of a substrate W.

As illustrated in FIG. 8, the ultrasonic vibration unit 1220 may be disposed such that a maximum distance d from the central axis C of the substrate support unit 1100 to the ultrasonic vibration unit 1220 may correspond to or be greater than a radius r of the substrate W. Accordingly, a rising portion of the chemical, formed by the ultrasonic vibration unit 1220, may clean even an edge of the substrate W. In the case of such a disposition, a coating liquid coated on an upper surface of the substrate W by an upper nozzle may be completely removed even when the coating liquid flows to a lower portion through the edge of the substrate w.

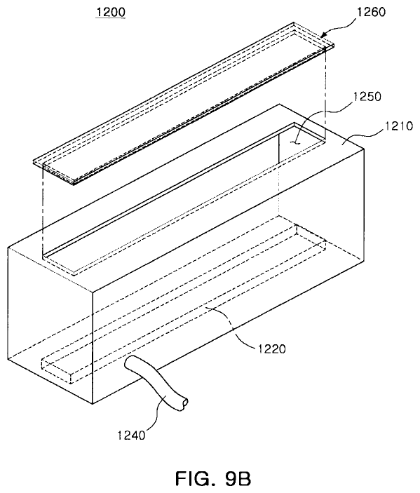

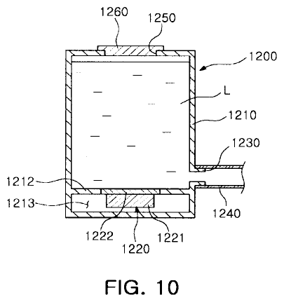

FIGS. 9A and 9B and FIG. 10 illustrate ultrasonic cleaning modules 1200 according to other embodiments.

As illustrated in FIGS. 9A and 9B, an ultrasonic cleaning module 1200 may include a receiving portion 1210 in which a chemical L is received, an opening portion 1250 exposing a portion of an upper surface of the receiving portion 1210, an ultrasonic vibration unit 1220 disposed inside the opening portion 1250 when viewed from above, a supply pipe 1240 connected to a chemical supply unit to supply the chemical L to the receiving portion 1210, a connection portion 1230 connected to the supply pipe 1240, and a cover 1260 having a shape corresponding to a shape of the opening portion 1250 to cover the chemical L inside the receiving portion 1210.

The ultrasonic vibration unit 1220 may be disposed directly below the opening portion 1250, and may include a vibration element 1221 and a vibration plate 1222 disposed between the vibration element 1221 and the chemical L inside the receiving portion 1210 and transmitting a vibration of the vibration element 1221 to the chemical L.

Unlike the embodiment of FIG. 7, in the present embodiment, an entire upper surface of the receiving portion 1210 may not be opened, and only an upper side portion of the ultrasonic vibration unit 1220 may be opened and the remaining portions may be covered with the receiving portion 1210. Accordingly, the opening portion 1250 may be formed only in a portion, in which a liquid surface rises due to the ultrasonic vibration unit 1220, for example, in a direction in which ultrasonic waves of the ultrasonic vibration unit 1220 are generated and travel, so that an area of the opening portion 1250 may be reduced. When the ultrasonic vibration unit 1220 is not used, the opening portion 1250 may be covered with the cover 1260 to prevent foreign objects from entering the chemical L inside the receiving portion 1210.

In addition, the chemical L supplied through the supply pipe 1240 is drawn from only a portion in which the liquid surface rises, for example, the opening portion 1250, which may efficiently help the ultrasonic vibration unit 1220 to raise the liquid surface LS.

The ultrasonic cleaning module 1200 according to the embodiment of FIG. 10 may include a receiving portion 1210 in which a chemical Lis received, an opening portion 1250 opening a portion of an upper surface of the receiving portion 1210, an ultrasonic vibration unit 1220 disposed on an internal side of the opening 1250 when viewed from above, a supply pipe 1240 connected to a chemical supply unit to supply a chemical to the receiving portion 1210, a connection portion 1230 connected to the supply pipe 1240, and a cover 1260 having a shape corresponding to a shape of the opening 1250 to cover the chemical inside the receiving portion 1210.

In the embodiment of FIG. 10, the receiving portion 1210 may include a partition plate 1212 partitioning an internal space of the receiving portion 1210. A space, in which the chemical L is received, and a space, in which a vibration element 1221 of the ultrasonic vibration unit 1220 is disposed, may be separated from each other by the partition plate 1212.

Similarly to other embodiments, the ultrasonic vibration unit 1220 may be disposed directly below the opening portion 1250 and may include a vibration element 1221 and a vibration plate 1222 disposed between the vibration element 1221 and the chemical L inside the receiving portion 1210 and transmitting a vibration of the vibration element 1221 to the chemical L.

A substrate processing apparatus 1000 according to present embodiment may include a substrate support unit 1100 supporting a substrate W, three ultrasonic cleaning modules 1200 arranged in a location lower than an upper surface of the substrate support unit 1100 and spaced apart from each other with respect to a central axis C of the substrate support unit 1100 at regular intervals, a cup 1300 surrounding the substrate support unit 1100, and a lower plate 1400 surrounding the substrate support unit 1100 below the substrate support 1100.

Each of the ultrasonic cleaning modules 1200 may include a receiving portion 1210 receiving the chemical L, an opening portion 1250 (see FIG. 7A) in which at least a portion of an upper surface of the receiving portion 1210 is opened, and an ultrasonic vibration unit 1220 disposed to be directed toward the opening portion 1250 from the receiving portion 1210, and may be configured such that a liquid surface of the chemical L rising by the ultrasonic vibration unit 1220 touches the substrate W through the opening portion 1250.

The three ultrasonic cleaning modules 1200 have the same shape, but frequencies of the ultrasonic waves generated by the vibration element 1221 of the ultrasonic vibration unit 1220 of each ultrasonic cleaning module 1200 (see FIG. 7A) are different from each other. In the present embodiment, the frequencies of all the ultrasonic vibration units 1220 are different from each other, but when a plurality of ultrasonic cleaning modules 1200 are present, frequencies of only some of the ultrasonic cleaning modules 1200 may be different from each other.

Features for each frequency are listed in Table 1. When a plurality of ultrasonic cleaning modules 1200 are included, removal efficiency of various types of particle may be improved using different frequencies.

TABLE 1

| | Single | Multi- | Medium | |
|---|---|---|---|---|
| | Frequency | Frequency | Frequency | |
| Item | (40 KHz) | (40-90 KHz) | (60-200 KHz) | Megasonic |
| Principle of | Cavitation | Cavitation | Cavitation, | Particle |
| Cleaning | | | Particle | Acceleration |
| | | | Acceleration | |
| Particle | 2500 G | 2500~ | 5000 G or | 100,000 G |
| Acceleration | | 5000 G | more | |
| Impact Force | Tens of | Tens of | Several | None |
| | Atmospheric | Atmospheric | Atmospheric | |
| | Pressures | Pressures | Pressures | |
| Feature | Strong | Linearity | Linearity | High |
| of Wave | Diffraction | | | Linearity |
| Removable | 2 μm or | 1.5 μm or | 1 μm or | 0.1 μm or |
| Particle | more | more | more | more |

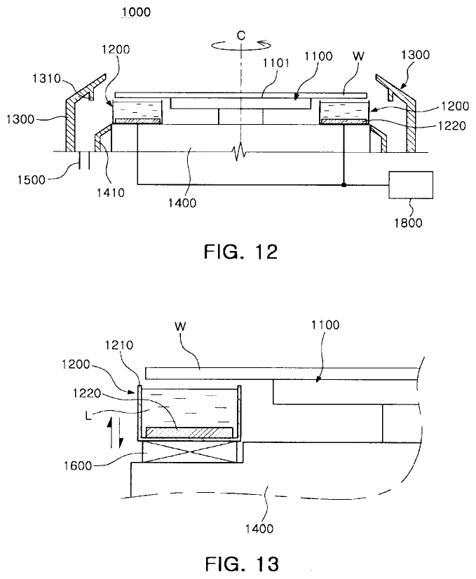

FIG. 12 illustrates a substrate processing apparatus 1000 according to another embodiment.

The substrate processing apparatus 1000 according to the present embodiment may include a substrate support unit 1100 supporting a substrate W, a plurality of ultrasonic cleaning modules 1200 disposed in a location lower than the upper surface 1101 of the substrate support unit 1100 and disposed in a location spaced apart from a central axis C of the substrate support unit 1100, a cup 1300 surrounding the substrate support unit 1100, a lower plate 1400 surrounding the substrate support unit 1100 below the substrate support unit 1100, a discharge pipe 1500 connected between the cup 1300 and the lower plate 1400, and a control unit 1800 connected to the ultrasonic cleaning module 1200.

In the present embodiment, the cup 1300 may include a protrusion 1310 extending downwardly from an inclined surface. A chemical, scattered by an upper nozzle or an underlying ultrasonic cleaning module 1200 through the protrusion 1310, may be guided to the discharge pipe 1500, and a coating liquid and a solvent may easily contact each other to facilitate a discharge of the scattered chemical to the discharge pipe 1500.

The lower plate 1400 may also further include a guide 1410 guiding the chemical, scattered from the ultrasonic cleaning module 1200, to the discharge pipe 1500.

A shape of the protrusion 1310 or the guide 1410 is not limited to that illustrated in the drawing, and the protrusion 1310 or the guide 1410 may have various shapes as long as it may be in helpful in discharging the coating liquid or the chemical.

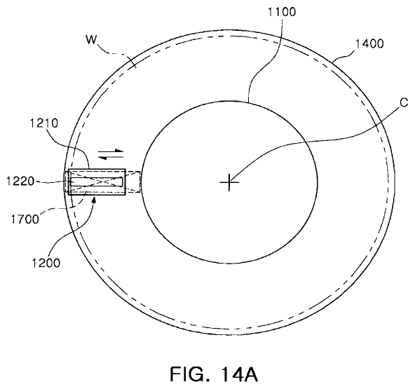

FIG. 13 illustrates a substrate processing apparatus 100 according to another embodiment. In the case of the embodiment of FIG. 13, a basic configuration is the same as that of the embodiment of FIG. 6, and thus a detailed description thereof will be omitted.

In the embodiment of FIG. 13, a substrate processing apparatus 100 may include a vertical movement unit 1600 disposed below an ultrasonic cleaning module 1200 to vertically move the ultrasonic cleaning module 1200. The vertical movement unit 1600 may be connected to a lower plate 1400, and the ultrasonic cleaning module 1200 may be connected on the vertical movement unit 1600.

The vertical movement unit 1600 may operate the ultrasonic cleaning module 1200 to move the ultrasonic cleaning module 1200 to a location, in which a liquid surface is to contact a lower surface of a substrate W, when the liquid surface rises, and may slightly move the ultrasonic cleaning module 1200 in a vertical direction while contacting the liquid surface to avoid a height at which a cleaning effect of ultrasonic waves does not occur.

In the case of ultrasonic waves, a phase of the ultrasonic waves may be zero (0) at half-wavelength intervals, and a cleaning effect of the ultrasonic waves may be reduced when a lower surface of the substrate W is disposed at the location. In the present embodiment, the ultrasonic cleaning module 1200 may be vertically moved by the vertical movement unit 1600 to a length of at least half of a wavelength or more during an ultrasonic cleaning process to fully exhibit a cleaning effect of ultrasonic waves.

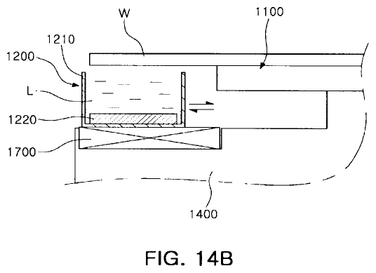

FIGS. 14A and 14B illustrate a substrate processing apparatus 1000 according to another embodiment. In the case of the embodiment of FIGS. 14A and 14B, a basic configuration is the same as that of the embodiment of FIG. 6, and thus a detailed description thereof will be omitted.

In the embodiment of FIGS. 14A and 14B, the substrate processing apparatus 1000 may include a radial movement unit 1700. The radial movement unit 1700 may be connected to a lower plate 1400, and an ultrasonic cleaning module 1200 may be connected to the radial movement unit 1700.

The radial movement unit 1700 may change a radial location of the ultrasonic cleaning module 1200, and may adjust a location cleaned in a lower portion of a substrate W to move the ultrasonic cleaning module 1200 to an insufficiently cleaned region or a region required to be further cleaned, thereby performing cleaning.

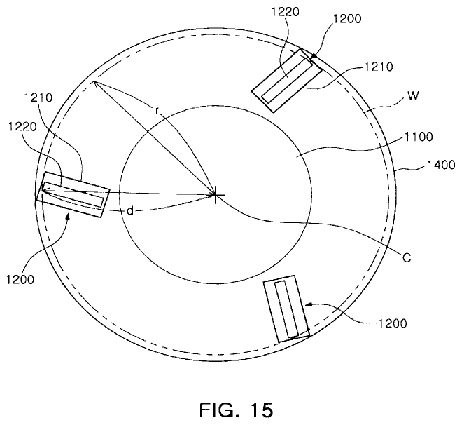

FIG. 15 illustrates a substrate processing apparatus 1000 according to another embodiment. In the case of the embodiment of FIG. 15, a basic configuration is the same as that of the embodiment of FIG. 6, and thus a detailed description thereof will be omitted.

In the embodiment of FIG. 15, an ultrasonic vibration unit 1220 of an ultrasonic cleaning module 1200 may not extend in a radial direction and may be disposed to extend with an angle of inclination with respect to the radial direction. Even in this case, a rising liquid surface may extend in the same direction as the direction in which an ultrasonic vibration unit 1220 extends. For example, a line formed by the rising liquid surface may be parallel to the direction in which the ultrasonic vibration unit 1220 extends.

Also in the present embodiment, the ultrasonic vibration unit 122 may be disposed such that a maximum distance d from a central axis C of a substrate support unit 1100 to the ultrasonic vibration unit 1220 may correspond to or be greater than a radius r of the substrate W. Accordingly, a rising portion of a chemical, formed by the ultrasonic vibration unit 1220, may clean even an edge of the substrate W.

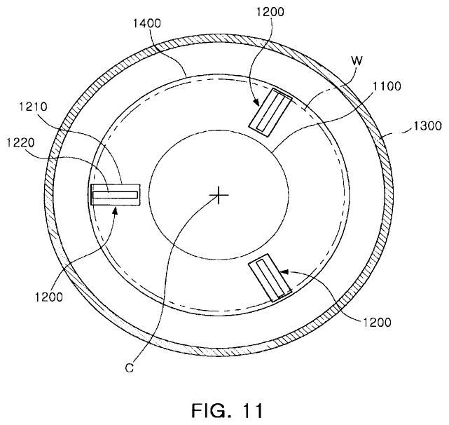

A disposition or a location of the ultrasonic cleaning module 1200 may be changed in various manners, other than the manners illustrated in FIGS. 11 and 15. When the location of the ultrasonic cleaning module 1200 corresponds to a location of a substrate W to be cleaned, the location or the disposition thereof is not limited to a specific location or a specific disposition.

The above-described substrate processing apparatus 1000 may be a part of the substrate processing apparatus 1 illustrated in FIGS. 1 to 3, but may also be used in a substrate processing apparatus performing only cleaning and may be used with or without an upper nozzle.

On the other hand, an embodiment of the present disclosure also provides a method of processing a substrate using ultrasonic waves.

A substrate processing apparatus 1000 used in the substrate processing method will be described with reference to FIG. 6. The substrate processing method may use the substrate processing apparatus 1000 including a substrate support unit 1100, supporting a substrate, and an ultrasonic cleaning module 1200 including a receiving portion 1210 receiving a chemical L and an ultrasonic vibration unit 1220 disposed to be directed toward an upper surface from the receiving portion 1210 and disposed to be lower than an upper surface of the substrate support unit 1110.

The substrate processing method may include a liquid surface rising operation in which, by operating the ultrasonic vibration unit 1220, a liquid surface LS of the chemical L received in the receiving portion 1210 rises to bring the chemical L into contact with a lower surface of a substrate W and a cleaning operation in which the lower surface of the substrate W rotated by the substrate support unit is cleaned while the liquid surface LS rises.

As described above, in the liquid surface rising operation, the ultrasonic vibration unit 1220 may provide an ultrasonic wave having a frequency of 40 KHz or more to the chemical L and may provide an ultrasonic wave having a frequency of 100 KHz or more to the chemical L.

When the lower surface of the substrate W is disposed in a location in which a phase of an ultrasonic wave becomes zero (0), a cleaning effect may be reduced. Therefore, in the cleaning operation, the ultrasonic cleaning module 1200 may be continuously moved in a vertical direction and a vertical moving distance may be greater than or equal to, in detail, half of a wavelength of the ultrasonic wave.

The ultrasonic cleaning module 1200 may be provided in plural, and the plurality of ultrasonic cleaning modules 1200 may provide ultrasonic waves having different frequencies. In addition, the ultrasonic cleaning module 1200 may rise or an output of the ultrasonic vibration unit 1220 may be adjusted, in consideration of a distance between the substrate W and the ultrasonic cleaning module 1200.

As described above, a substrate processing apparatus and a substrate processing method for cleaning a lower portion of a substrate using ultrasonic waves may be provided to improve cleaning of a lower portion of a substrate.

While example embodiments have been shown and described above, it will be apparent to those skilled in the art that modifications and variations could be made without departing from the scope of the present disclosure as defined by the appended claims.

What is claimed is:

1. A substrate processing apparatus comprising:
a substrate support unit supporting a substrate; and
an ultrasonic cleaning module disposed in a location lower than an upper surface of the substrate support unit,
wherein
the ultrasonic cleaning module includes a receiving portion receiving a chemical, an opening portion in which at least a portion of an upper surface of the receiving portion is opened, and an ultrasonic vibration unit disposed to be directed toward the opening portion from the receiving portion, and is configured in such a manner that a liquid surface of the chemical, rising by the ultrasonic vibration unit, touches the substrate through the opening portion.

2. The substrate processing apparatus of claim 1, wherein
the opening portion opens an upper surface of the receiving portion with a shape corresponding to a shape of the ultrasonic vibration unit when viewed from above.

3. The substrate processing apparatus of claim 1, wherein
a first length of the ultrasonic vibration unit in a radial direction of the substrate is greater than a second length of the ultrasonic vibration unit in a direction, perpendicular to the radial direction.

4. The substrate processing apparatus of claim 1, further comprising:
a cover covering the opening portion; and
a supply pipe connected to a chemical supply unit to supply the chemical to the receiving portion,
wherein
an area of the opening portion is larger than a cross-sectional area of the supply pipe.

5. The substrate processing apparatus of claim 2, wherein
the ultrasonic vibration unit extends in a radial direction of the substrate.

6. The substrate processing apparatus of claim 1, further comprising:
a control unit connected to the ultrasonic cleaning module,
wherein
the control unit adjusts an output supplied to the ultrasonic vibration unit to allow the liquid surface of the chemical, rising by the ultrasonic vibration unit, to touch the substrate through the opening portion.

7. The substrate processing apparatus of claim 1, comprising:
a plurality of ultrasonic cleaning modules surrounding a rotational axis of the substrate support unit and arranged in a circumferential direction at regular intervals.

8. The substrate processing apparatus of claim 7, wherein
at least one of ultrasonic vibration units of the ultrasonic cleaning modules provides an ultrasonic wave having a frequency, different from a frequency of another ultrasonic vibration unit.

9. The substrate processing apparatus of claim 1, further comprising:
a vertical movement unit connected to the ultrasonic cleaning module and moving the ultrasonic cleaning module in a vertical direction.

10. The substrate processing apparatus of claim 9, further comprising:
a radial movement unit connected to the ultrasonic cleaning module and moving the ultrasonic cleaning module in a radial direction of the substrate.

11. The substrate processing apparatus of claim 1, wherein
the substrate support unit is configured to rotate about a rotational axis of the substrate support unit, and
a maximum distance from the rotational axis of the substrate support unit to the ultrasonic vibration unit is greater than a maximum radius of the substrate.

12. The substrate processing apparatus of claim 1, further comprising:
a lower plate surrounding the substrate support unit below the substrate support unit; and
at least one cup covering an external side of the substrate support portion,
wherein
the ultrasonic cleaning module is seated on the lower plate.

13. The substrate processing apparatus of claim 12, wherein
an exhaust unit is formed between the cup and the substrate support unit, and
an internal surface of the cup is provided with a protrusion extending toward the exhaust unit.

14. A substrate processing apparatus comprising:
a substrate support unit supporting a substrate and configured to rotate about a rotational axis;
an ultrasonic cleaning module disposed on an external side of the substrate support unit in a location lower than an upper surface of the substrate support unit;
a lower plate surrounding the substrate support unit below the substrate support unit and on which the ultrasonic cleaning module is seated; and
at least one cup covering an external side of the substrate support unit,
wherein
the ultrasonic cleaning module includes a receiving portion receiving a chemical, an opening portion in which at least a portion of an upper surface of the receiving portion is opened, and an ultrasonic vibration unit disposed to be directed toward the opening portion from the receiving portion, and is configured in such a manner that a liquid surface of the chemical, rising by the ultrasonic vibration unit, touches the substrate through the opening portion, and
the ultrasonic vibration unit extends in a radial direction of the substrate, and a first length of the ultrasonic vibration unit in a radial direction of the substrate is greater than a second length of the ultrasonic vibration unit in a direction, perpendicular to the radial direction.

15. The substrate processing apparatus of claim 14, further comprising:
a vertical movement unit connected to the ultrasonic cleaning module and moving the ultrasonic cleaning module in a vertical direction.

16. The substrate processing apparatus of claim 14, comprising:
a plurality of ultrasonic cleaning modules surrounding a rotational axis of the substrate support unit and arranged in a circumferential direction at regular intervals, wherein
ultrasonic vibration units of the ultrasonic cleaning modules provide ultrasonic waves having different frequencies to the chemical.

17. The substrate processing apparatus of claim 14, wherein
the ultrasonic cleaning module further includes a cover opening and closing the opening portion.

18. A method for processing a substrate using a substrate processing apparatus including a substrate support unit, supporting a substrate, and an ultrasonic cleaning module including a receiving portion receiving a chemical and an ultrasonic vibration unit disposed to be directed toward an upper surface from the receiving portion and disposed to be lower than an upper surface of the substrate support unit, the method comprising:
a liquid surface rising operation in which, by operating the ultrasonic vibration unit, a liquid surface of the chemical received in the receiving portion rises to bring the chemical into contact with a lower surface of a substrate; and
a cleaning operation in which the lower surface of the substrate, being rotated, is cleaned while the liquid surface rises.

19. The method of claim 18, wherein
in the liquid surface rising operation, the ultrasonic vibration unit provides an ultrasonic wave having a frequency of 40 KHz or more.

20. The method of claim 18, wherein
in the cleaning operation, the ultrasonic cleaning module moves in a vertical direction.
